(19) United States
(12) Patent Application Publication
(10) Pub. No.: US 2011/0143930 A1
(43) Pub. Date: Jun. 16, 2011

(54) TUNABLE SIZE OF NANO-ACTIVE MATERIAL ON NANO-SUPPORT

(75) Inventors: Qinghua Yin, Tempe, AZ (US); Xiwang Qi, Scottsdale, AZ (US); Maximilian A. Biberger, Scottsdale, AZ (US); David Leamon, Gilbert, AZ (US)

(73) Assignee: SDCMATERIALS, INC., Tempe, AZ (US)

(21) Appl. No.: 12/962,518

(22) Filed: Dec. 7, 2010

Related U.S. Application Data
(60) Provisional application No. 61/284,329, filed on Dec. 15, 2009.

(51) Int. Cl. B01J 23/42; B01J 35/02; B01J 21/04; B01J 21/08; B01J 21/06; B01J 21/18; B01J 21/12; C23C 16/52; B82Y 30/00

(52) U.S. Cl. 502/180; 502/100; 502/355; 502/232; 502/350; 502/263; 502/339; 118/715; 977/775

(57) ABSTRACT

A method of tuning the size of an nano-active material on a nano-carrier material comprising: providing a starting portion of a carrier material and a starting portion of an active material in a first ratio; adjusting the first ratio, forming a second ratio, thereby tuning the ratio of active material and carrier material; combining the portion of the active material in a vapor phase and the portion of the carrier material in a vapor phase, forming a conglomerate in a vapor phase; and changing the phase of the conglomerate, thereby forming nano-spheres comprising a nano-carrier material decorated with a nano-active material, wherein the size of the nano-active material is dependent upon the second ratio.

### CROSS-REFERENCE TO RELATED APPLICATIONS

This application claims priority to U.S. Provisional Patent Application Ser. No. 61/284,329, filed Dec. 15, 2009 and entitled “MATERIALS PROCESSING,” which is hereby incorporated herein by reference in its entirety as if set forth herein.

### FIELD OF THE INVENTION

The present invention relates to the field of the manufacture of nano-active materials. More particularly, the present invention relates to optimizing and customizing the size and concentration of a nano-active material on a substructure.

### BACKGROUND OF THE DISCLOSURE

Nano-materials are quickly becoming commonplace in the scientific community as well as in commercial and industrial applications. Methods of conducting mechanical and chemical reactions oftentimes utilize nano-particles by themselves. However, other practices involve using a substructure to support a nano-scale component of a reaction. Oftentimes, nano-particles are impregnated into a substructure and the substructure processed, bonding the nano-particles to the walls of the substructure (i.e. calcination). One advantage to calcinating substructures containing nano-particles is that the particles will remain bonded to the substructure as fluid passes over it and reacts with the particles.

Many applications utilize catalysts to help in a reaction. In some applications, it is desirable to utilize small-scale catalysts on the order of nano-sized catalysts, such as nano-particles. Furthermore, it is also oftentimes desirable to use support structures to provide a substructure upon which the nano-particles reside. According to these processes, it is necessary to impregnate the substructure with the nano-sized catalysts.

Various methods of manufacturing nano-particles exist in the art. Methods of manufacturing nano-particles to be used as catalysts sometimes require the catalyst material itself and a carrier material upon which the catalyst is able to bond to when in a nano-sized state. Often times the practice of combining a catalyst and a carrier is accomplished by delivering the two materials to a combination chamber while the catalyst and the support are in a vapor or plasma state. The “clouds” of material are rapidly quenched and a combination material is provided in a solid nano-sized state. Next, a dispersion is created with the nano-sized combination material, a liquid and an adjunct additive causing mutual repulsion between near combination material particles. Next, this dispersion is impregnated into a support sub-structure. Finally a step of drying and calcination is performed to remove the liquid and bind the combination nano-particles to the substructure.

However, current methods of fabricating nano-particles on support substructures suffer from the lack of precision in controlling the size of the nano-active particles and the lack of a means for precise control over the total amount (or load) of nano-active material in a substructure. These deficiencies in the art lead to unsatisfactory or imprecise reactions and reaction rates.

### SUMMARY OF THE DISCLOSURE

The present invention discloses systems and methods of controlling the size of nano-particles on a support substructure. The present invention also discloses systems and methods of controlling the overall load of nano-particles within the substructure.

In some embodiments of the present invention, systems and methods are provided to control the size of a nano-active material on a carrier material, wherein the resulting particle is used in a catalytic process. This can be achieved by controlling the ratio of nano-active material and carrier material provided within a combination chamber.

In other embodiments of the present invention, systems and methods of performing multiple iterations of an impregnation step and a drying/calcination step are utilized to control the total amount of nano-active material with a substructure. According to these embodiments, the useful life of a substructure can be controlled.

In yet other embodiments of the present invention, the size of the nano-active particles is controlled and multiple iterations of the impregnation step are performed to control and ensure desired particle size and overall nano-active material loading within a substructure. According to these embodiments, the chemical selectivity and chemical activity of the loaded substructure can be precisely controlled.

### BRIEF DESCRIPTION OF THE DRAWINGS

FIG. 1 illustrates one embodiment of the process steps of controlling the size of a nano-particles on a support substructure in accordance with the principles of the present invention.

FIG. 2A illustrates one embodiment of a process of forming nano-active material on a nano-carrier and determining how the ratio of the starting material affects the size of the nano-active material and impregnating the nano-spheres into a substructure in accordance with the principles of the present invention.

FIG. 2B illustrates one embodiment of a process of calibrating a system of manufacturing nano-spheres where a number of iterations of the manufacturing process are performed using different combinations of starting material and recording the size of the resulting nano-spheres in accordance with the principles of the present invention.

FIG. 3 illustrates an isometric schematic view of one embodiment of an extrudate in accordance with the principles of the present invention.

FIG. 4 illustrates a basic schematic diagram of one embodiment of an apparatus designed for manufacturing tunable-sized nano-materials within a substructure in accordance with the principles of the present invention.

FIG. 5 illustrates one embodiment of a process of increasing the overall loading of a substructure while maintaining desired particle size in accordance with the principles of the present invention.

### DETAILED DESCRIPTION

Reference will now be made in detail to the embodiments of the methods and systems of manufacturing, examples of which are illustrated in the accompanying drawings. While the methods and systems will be described in conjunction with the embodiments below, it will be understood that they are not intended to limit the methods and systems of these embodiments and examples. On the contrary, the methods and systems are intended to cover alternatives, modifications and equivalents, which may be included within the spirit and scope of the methods and systems as defined by the appended claims. Furthermore, in the following detailed description, numerous specific details are set forth in order to more fully illustrate the methods and systems. However, it will be apparent to one of ordinary skill in the prior art that the methods and systems may be practiced without these specific details. In other instances, well-known methods and procedures, components and processes have not been described in detail so as not to unnecessarily obscure aspects of the optical detection module and recursive algorithm.

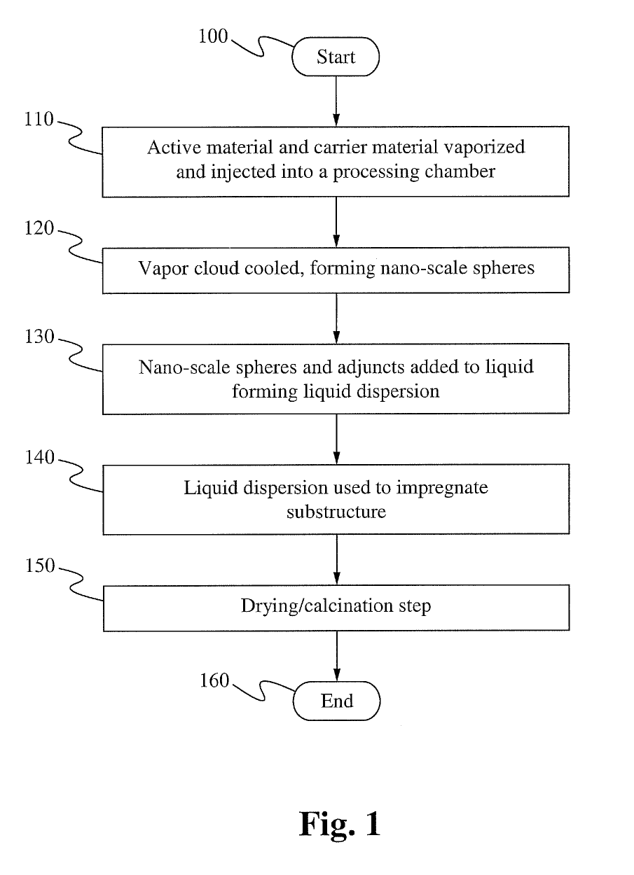

FIG. 1 illustrates the process steps of manufacturing nano-particles on a support substructure. Examples of such processing systems are further described in U.S. patent application Ser. No. 12/001,643, filed on Dec. 11, 2007, and entitled “METHOD AND SYSTEM FOR FORMING PLUG AND PLAY METAL CATALYSTS”, U.S. patent application Ser. No. 12/474,081, filed on May 28, 2009, and entitled “METHOD AND SYSTEM FOR FORMING PLUG AND PLAY METAL CATALYSTS”, U.S. patent application Ser. No. 12/001,602, filed on Dec. 11, 2007, and entitled “METHOD AND SYSTEM FOR FORMING PLUG AND PLAY METAL COMPOUND CATALYSTS”, U.S. patent application Ser. No. 12/001,644, filed on Dec. 11, 2007, and entitled “METHOD AND SYSTEM FOR FORMING PLUG AND PLAY OXIDE CATALYSTS”, SDC-04800, filed herewith and entitled “PINNING AND AFFIXING NANO-ACTIVE MATERIAL”, and U.S. Provisional Patent Application No. 60/928,946, entitled “MATERIAL PRODUCTION SYSTEM AND METHOD”, which are incorporated herein by reference in their entireties.

According to FIG. 1, the manufacturing process begins at start step 100. At start step 100, an active material and a carrier material are provided at a first ratio. In the preferred embodiment of the present invention, the ratio of active material and carrier material injected into the processing chamber is known. The active material is selected for its propensity to react with other materials, depending upon the desired application, among other considerations. Likewise, the carrier material is selected for its propensity to bond with the active material, among other considerations. At step 110, the active materials and the carrier materials are vaporized and injected into a processing chamber, forming a vapor cloud. At step 120, the vapor cloud is rapidly cooled. In some embodiments of the present invention, the vapor cloud is cooled by quenching the vapor cloud with a liquid. As the vapor cloud is cooled, the vaporized carrier material and vaporized active material cool and bond together, forming nano-scale spheres comprising nano-carrier particles decorated with nano-active material particles.

In some embodiments of the present invention, the resulting nano-active material particles are less than 0.5 nm. In other embodiments, the resulting nano-active material particles range between 0.5 nm and 10 nm. In yet other embodiments, the resulting nano-active material particles are larger than 10 nm. For the purpose of this disclosure and the claimed invention, the term nano-sphere shall refer to any small scale particle that is at least partially spherically shaped with a size less than about 1000 nanometers.

Next, at step 130, the nano-scale spheres and a portion of adjuncts are added to a liquid, forming a liquid dispersion. The adjuncts are chosen for their ability to support mutual repulsion between adjacent nano-scale spheres. In some embodiments of the present invention, the adjuncts are an organic material.

At step 140, the liquid dispersion is used to impregnate a porous substructure. In some embodiments of the present invention, the substructure is a nano-scale substructure. In some embodiments of the present invention, the substructure is a ceramic substructure. In some embodiments of the present invention, the liquid dispersion is added to a container containing one or more porous substructures and allowed to impregnate the substructure naturally. In other embodiments of the present invention, the liquid dispersion is forced through one or more porous substructures. Next, at step 150 a drying/calcination step is performed to bond the nano-spheres to a surface within the porous substructure. The process ends at step 160.

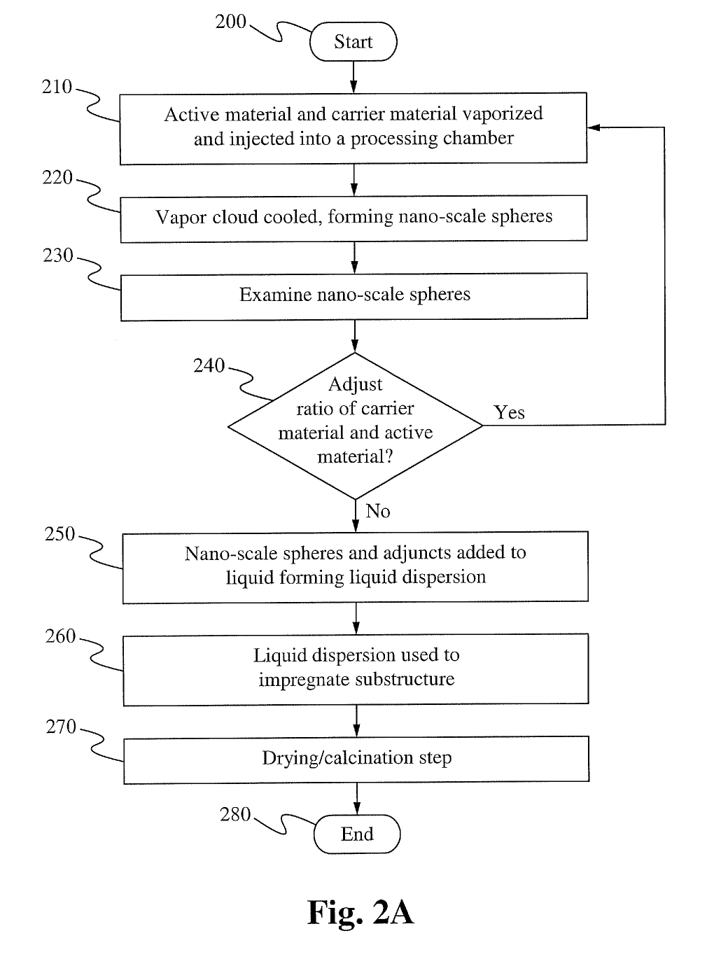

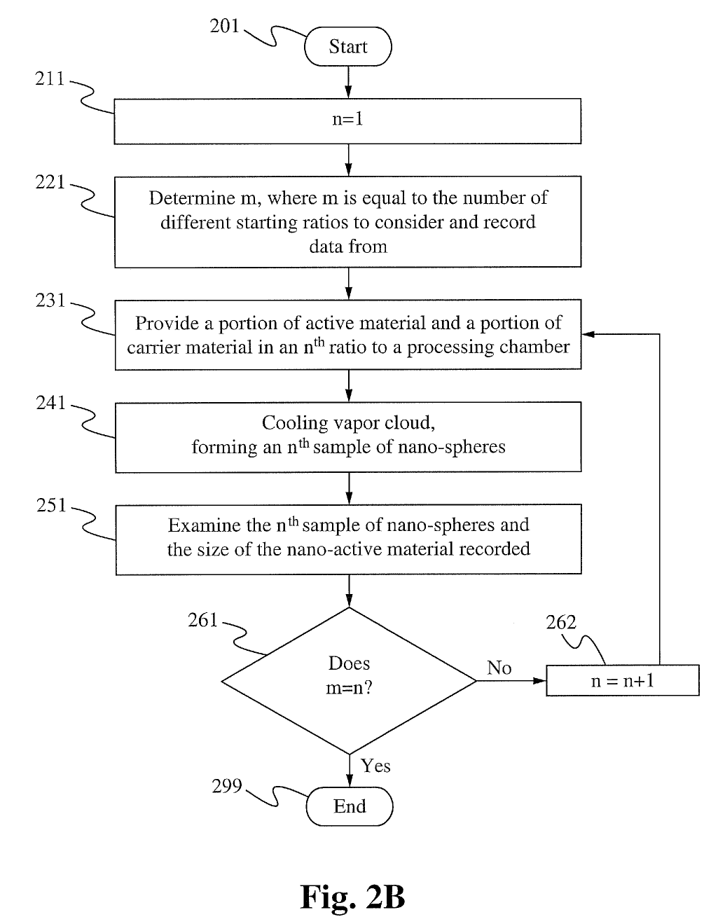

It has been observed that the size of the nano-carrier material formed from cooling the vapor cloud is a function of system conditions, such as the time taken to cool the vapor cloud. However, the size of the nano-active material decorated upon the surface of the carrier material has been observed to be a function of the ratio of active material and carrier material vaporized. It has been observed that as the amount of pre-injection active material increases in relation to pre-injection carrier material, the particle size of the resulting post-cooling nano-active particle size increases. Likewise, as the amount of pre-injection active material decreases in relation to pre-injection carrier material, the particle size of the resulting post-cooling nano-active particle size decreases. This results from the probability of vaporized active material being found near other vaporized active material as the vapor is cooled and the vapor turns into particles. Accordingly, it is an object of the present invention to adjust the pre-injection ratio of active material to carrier material in order to tune the resulting size of the nano-active material decorated on the nano-carrier material. FIG. 2A illustrates an embodiment of a process of forming nano-active material on a nano-carrier and determining how the ratio of the starting material affects the size of the nano-active material and impregnating the nano-spheres into a substructure.

At start step 200, active material and carrier material are provided at an initial ratio. At step 210, the active materials and the carrier materials are vaporized and injected into a processing chamber, forming a vapor cloud. At step 220, the vapor cloud is rapidly cooled, forming nano-scale spheres comprising nano-carrier particles decorated with nano-active material particles.

Next, at step 230, the nano-scale spheres are examined. In some embodiments of the present invention, a tunneling electron microscope is utilized to examine the nano-spheres, however it will become readily apparent to those having normal skill in the relevant art that a number of microscopy techniques, now present or later developed may be used to examine the nano-spheres. In other embodiments of the present invention, other means of examining the nano-spheres is utilized. For example, chemisorption techniques may be utilized to analyze the nano-spheres. Furthermore, other techniques of observing the nano-spheres will be readily apparent to those having ordinary skill in the art.

Next, at step 240, a choice is made whether to adjust the ratio of the starting material (i.e. the active-material and the carrier-material). The ratio of the starting materials are adjusted and injected into a chamber in a new ratio and are again vaporized at step 210, the vapor cooled at step 220 and the resulting nano-scale spheres are again examined. In some embodiments of the present invention, this process is repeated until the desired size nano-active material is found on the nano-carrier material of the nano-spheres. Once the desired size of the nano-active material is achieved, the adjustment step 240 is completed and the nano-scale spheres and a portion of adjuncts are added to a liquid at step 250, forming a liquid dispersion. At step 260, the liquid dispersion is used to impregnate a porous substructure. At step 270, a drying/calcination step is performed to bond the nano-spheres to a surface within the porous substructure. The process ends at step 280.

The resulting nano-spheres are able to be used in any variety of applications including, mechanical and chemical processes. In some embodiments of the present invention, the nano-active material is a catalyst. In some embodiments of the present invention, the nano-active material is nano-platinum and the substructure impregnated with nano-active platinum is utilized as a catalyst in oil refining applications.

In some embodiments of the present invention, a process of calibration is conducted to determine how the ratio of active material to carrier material affects the size of nano-active material on a nano-carrier material for any suitable combination of active material and carrier material. FIG. 2B illustrates an embodiment of a process of calibrating a system of manufacturing nano-spheres where a number of iterations of the manufacturing process are performed using different combinations of starting material and recording the size of the resulting nano-spheres.

At start step 201, active material and carrier material are provided. At step 211, a first occurrence of determining the relationship between the ratio of starting material and the size of nano-active particles begins. The number of iterations n is set to one, where n is an integer. Next, at step 221 the number m is determined, where m is equal to the number of different starting ratios to consider and record data from. Next, at step 231, a portion of active material in a vapor phase and a portion of carrier material in a vapor phase are combined in a n^{th} ratio, forming a conglomerate vapor cloud. At step 241, the conglomerate vapor cloud is cooled, forming a n^{th} sample of nano-spheres. At step 251, the n^{th} sample of nano-spheres is examined and the size of the nano-active particles littered on the nano-carrier material is recorded. Next, at step 261, the number of different starting ratios, m, is considered and if that number is reached, the process ends at step 299. If the number m has not been reached, the integer n is increased by 1 at step 262 and the process repeats starting over at step 231. When the appropriate number of ratios have been considered, the process ends at step 299. When the process ends at step 299, the data is organized for later use.

After a process of calibration is done for a given set of starting materials, a process of manufacturing nano-spheres having a certain sized nano-active material may be accomplished without examining the nano-spheres, but rather by simply using the appropriate ratio of starting material as has been previously identified and recorded.

In the preferred embodiment, the size-tuned nano-particles are made to be used in chemical reactions. However, it is oftentimes the case that the nano-particles themselves, are not particularly useful in a chemical reaction because they will be quickly washed away when used with a liquid. Therefore, it is an object of the present invention to present the nano-particles in a useful form that can be used effectively in a chemical reaction. In some embodiments of the present invention, once size-tuned nano-particles are made, they are impregnated into a miniature substructure and bonded therein. In the preferred embodiment of the present invention, the substructure is an extrudate. For example, in oil refining and fine chemical reactions, an extrudate is the preferred means for exposing nano-active particles to the reaction.

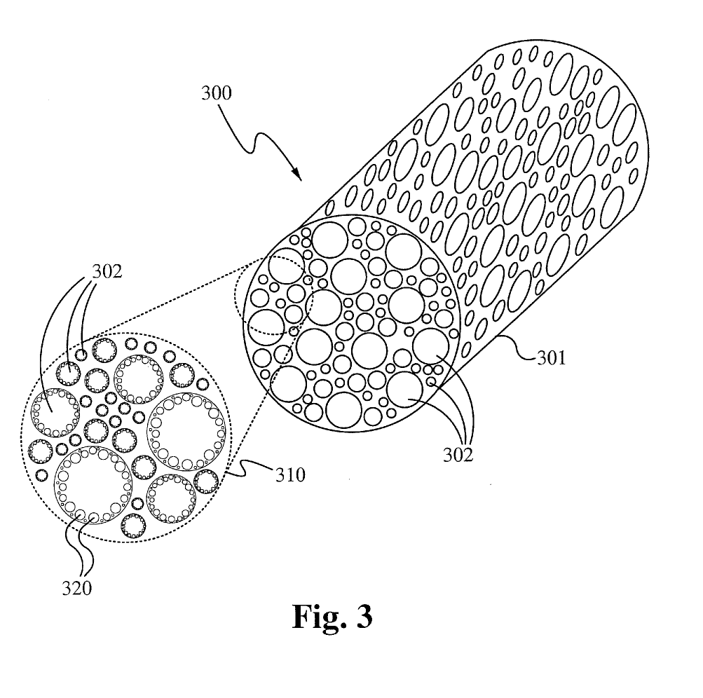

FIG. 3 illustrates an isometric schematic view of an extrudate 300 according to some embodiments of the present invention. In the preferred embodiment of the present invention, the extrudate 300 is substantially cylindrical and ranges between 3 millimeters and 5 millimeters in length and has a diameter of approximately 2 millimeters. Also in the preferred embodiment, the extrudate 300 is a highly porous ceramic structure comprising a rigid portion 301 and pores 302. In some embodiments of the present invention, the extrudate has a pore volume to weight ratio on the order of 0.5 millimeters per one gram of extrudate. As such, a liquid dispersion containing nano-spheres, as explained at step 140 above, is able to be impregnated into the pore volume of the extrudate 300.

Referring to FIG. 1, the dispersion containing nano-spheres is impregnated into a substructure at step 140 and then a drying/calcining step is undertaken at step 150. The drying and calcining step 150 involves exposing the impregnated substructures to a first temperature to dry the substructures by evaporating the liquid portion of the dispersion. Next, the dried substructures are brought to a second temperature, wherein the second temperature supports calcining such that the nano-spheres are oxidized to the pores of the substructure. Referring again to FIG. 3, a close-up view 310 of the extrudate 300 is shown after being once-impregnated with a dispersion and after a step of drying/calcining has been performed. As shown, a number of nano-spheres 320 (not to scale) have been bonded to the walls of the pores 302. The nano-spheres 320 comprise nano-carrier material decorated with nano-active material.

As shown in FIG. 3, each impregnation takes up a small percentage of pore volume because the portion of the dispersion is evaporated during the drying step. Therefore, it may be desirable to perform more than one iteration of the impregnation step and the drying/calcining step in order to increase the overall loading of a substructure (explained below).

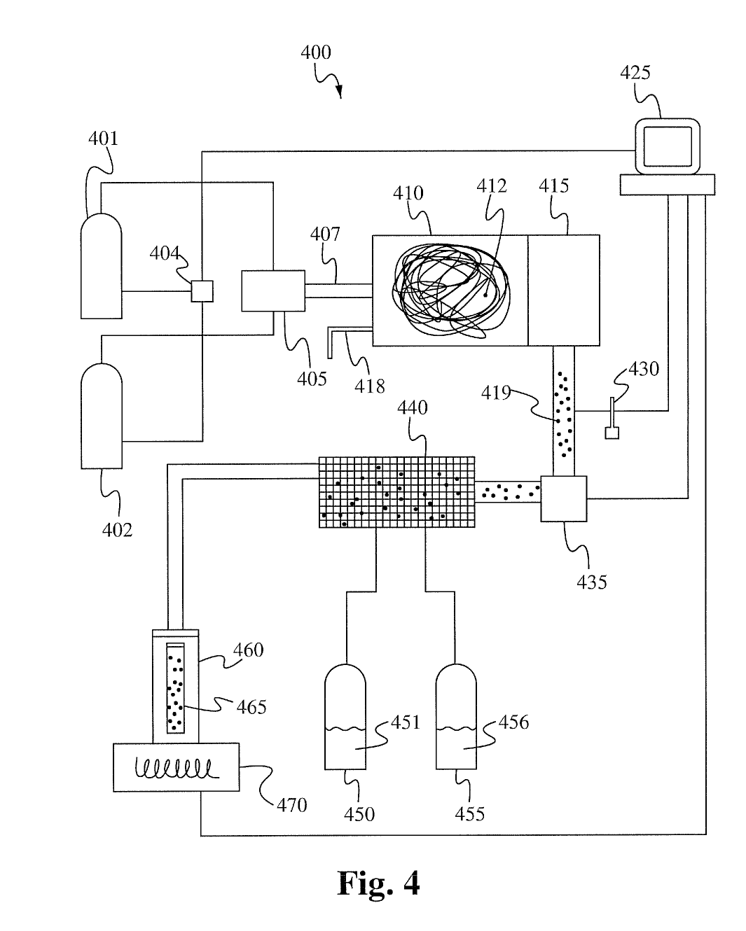

In some embodiments of the present invention, an apparatus is disclosed for manufacturing nano-spheres and impregnating a substructure with the nano-spheres. FIG. 4 illustrates a basic schematic diagram of an apparatus 400 designed for manufacturing tunable-sized nano-materials within a substructure according to an embodiment. A first supply tank 401 and a second supply tank 402 supply carrier material and active material, respectively, to a vaporizer 405. In some embodiments of the present invention, a control module 404 is coupled to the first supply tank 401 and the second supply tank 402. According to these embodiments, the control module 404 controls the ratio of carrier material to active material supplied to the vaporizer 405. In other embodiments the ratio is control by some other means including, but not limited to, manual control. In some embodiments of the present invention, the control module 404 is coupled to the first supply tank 401 and the second supply tank, and also to a computer 425. According to these embodiments, the computer 425 instructs the control module 404 the ratio of carrier material to active material to be supplied to the vaporizer 405. In some embodiment of the present invention, the computer's 425 instruction is based on information delivered to the computer from an examination instrument 430, such as a microscope (explained below).

Once carrier material and active material is delivered to the vaporizer 405, it vaporizes the material and supplies the vaporized material to an injector gun 407. The injector gun 407 delivers vaporized material to a processing chamber 410. The vaporized material takes the form of a vapor cloud 412 within the processing chamber 410. Within the vapor cloud 412 is a concentration of vaporized active material and carrier material in some ratio.

In some embodiments of the present invention, a bleed line 418 is provided to evacuate the processing chamber 410. For example, it may be desirable to completely evacuate the processing chamber 410 after providing a first ratio of vaporized active material and vaporized carrier material before providing a second ratio of vaporized active material and vaporized carrier material.

The vapor cloud 412 is then cooled by cooling means 415. As the vapor cloud cools the vaporized active material and the vaporized active material bond together, forming nano-scale spheres 419 (indicated with a dot pattern) within supply means 420. The nano-scale spheres generally comprise a ball (not shown) of carrier material decorated with dots (not shown) of nano-active material. The size of the dots is dependent on the ratio of carrier material to active material supplied to the vaporizer 405.

In some embodiments of the present invention, the nano-scale spheres are examined by an examination instrument 430. According to these embodiments, a tunneling electron microscope is preferably used as the examination instrument 430, however it will become readily apparent to those having normal skill in the relevant art that a number of microscopy techniques, now present or later developed, may be used to examine the nano-spheres. In other embodiments of the present invention, chemisorption techniques can be utilized to analyze the nano-spheres. Furthermore, other techniques of observing the nano-spheres will be readily apparent to those having ordinary skill in the art.

In some embodiments of the present invention, the size of the nano-active material on the nano-spheres are examined. According to these embodiments, an operator is able to change the ratio of starting materials to tune the size of the nano-active materials. In some embodiments of the present invention, a controllable valve 435 is utilized to purge unwanted nano-spheres having nano-active material of an undesirable size and to allow size-tuned nano-particles through to be further processed. In some embodiments of the present invention, the controllable valve 435 is coupled to and controlled by the computer 425.

Once nano-spheres are produced having a desirable size, the nano-spheres are directed to a receptacle 440 and added to a liquid dispersion (indicated with a checkerboard pattern). In some embodiments of the present invention, a first chemistry tank 450 and a second chemistry tank 455 supply a liquid 451 and a portion of adjuncts 456, respectively, to the receptacle 440 to make up the liquid dispersion. The adjuncts 456 are chosen for their ability to support mutual repulsion between adjacent nano-scale spheres. In some embodiments of the present invention, the adjuncts 456 are an organic material.

The liquid dispersion is then directed to a chamber 460 and used to impregnate one or more substructures 465. A heating element 470 is provided for drying and calcination of the one or more substructures 465.

In some embodiments of the present invention, the computer 425 is coupled to the control module 404, the bleed line 418, the examination instrument 430, the controllable valve 435 and the heating element 470. According to these embodiments, the apparatus is fully automated based on instructions entered by an operator into the computer 425.

### Activity or Selectivity

Once a new combination of active and carrier starting materials are chosen, it is desirable to calibrate the system in order to find how the ratio of starting material affects the size of the nano-active material decorated on the nano-carrier material. It is useful to be able to control the size of the nano-active material because the chemical activity of a nano-particle is oftentimes dependent on the size of the nano-particle. Therefore, depending upon the application and the size-dependent activity of the active material, one may desire a particular sized nano-active particle. As such, the particle size of the nano-active material is able to be adjusted to a particular size based on the calibration data according to some embodiments of the present invention. In some embodiments of the present invention, the particle size of the nano-active material is minimized. In some embodiments, the size of the nano-active material is minimized and multiple iterations of the impregnation step and the calcination step are performed to adjust the overall load of nano-active material within a substructure while maintaining the smallest possible scale (method discussed below).

### Loading the Substructure

As explained above, there are common mechanical and chemical applications which benefit from the use of nano-active materials. The size of the nano-active materials is important to these reactions because the chemical activity of the nano-active material changes with the size of the particles. It is also important to control the overall loading of a substructure in order to control the activity of chemical reactions. In general, the higher the overall loading of a substructure with nano-active material, the occurrence of the desired chemical reactions will take place at a greater rate as a desired chemistry is exposed to the to nano-active material located on the substructure (higher activity). One method of increasing activity is to increase the size of the nano-active material within the substructure because a larger surface area of active material will be exposed. However, as explained above, smaller particles of nano-active material are often needed to achieve the appropriate selectivity for a given application. Therefore, a method of increasing the overall loading (to increase activity) of a substructure while maintaining desired particle size (selectivity) is disclosed.

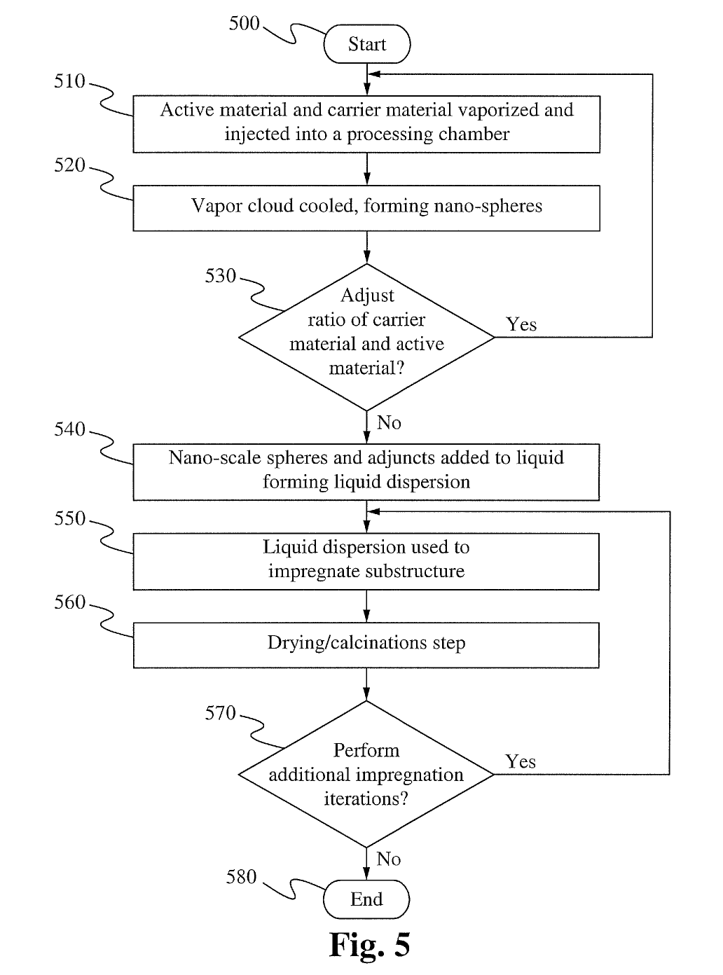

FIG. 5 illustrates a process of increasing the overall loading of a substructure while maintaining desired particle size according to an embodiment. At start step 500, active material and carrier material are provided at an initial ratio. At step 510, the active material and the carrier material are vaporized and injected into a processing chamber, forming a vapor cloud. At step 520, the vapor cloud is rapidly cooled, forming nano-scale spheres comprising nano-carrier particles decorated with nano-active material particles.

Next, at step 530, a choice is made whether to tune the size of the nano-active material decorated on the nano-spheres by adjusting the ratio of the starting materials (i.e. the carrier material and the active material). In the preferred embodiment of the present invention, the size of the nano-active particles is minimized. When the size of the nano-active material is tuned to the desired size, the nano-scale spheres and a portion of adjuncts are added to a liquid at step 540, forming a liquid dispersion. At step 550, the liquid dispersion is used to impregnate a porous substructure. At step 560, a drying/calcination step is performed to bond the nano-spheres to a surface within the porous substructure.

Next, at step 570, the impregnated substructures are examined to determine the overall loading of nano-spheres within and a decision is made whether to perform one or more impregnation iteration. As explained above, the size of the nano-active particles is minimized at step 530. According to this embodiment, the overall loading is able to be finely adjusted by performing one or more iterations of the impregnation step 550 and drying/calcination step 560 with the smallest common particle size. Subsequent iterations of impregnation increase the overall loading because the amount of space consumed by the nano-spheres within the substructure is very small compared to the total porous space available within the substructure. Once the size of the nano-active material is selected and the overall loading of the substructure is optimized, the process ends at step 580.

Oftentimes, a certain sized nano-active particle is desired based upon a given application due to the given reaction's chemical selectivity restraints. Furthermore, it is often desirable to increase the chemical activity of this reaction as well. In some embodiments of the present invention, a minimum sized nano-active material is manufactured on a nano-carrier material and a maximum amount of these resulting nano-spheres are impregnated into a support structure. As such, the effectiveness of the support structure and the active life of the substructure is maximized.

In some embodiments of the present invention, the active material is chosen for its propensity to serve as a catalyst and the carrier material is chosen for its propensity to bond to the active material. In some embodiments of the present invention, platinum is chosen as the catalyst and aluminum is chosen as a carrier material. In other embodiments, the carrier material is selected from among Al₂O₃, Si₂O₂, TiO₂, C, AlSiO₃, among other compounds. According to these embodiments, the size of the nano-active material is generally independently tunable regardless of the carrier material chosen.

The present invention has been described in terms of specific embodiments incorporating details to facilitate the understanding of principles of construction and operation of the invention. Such reference herein to specific embodiments and details thereof is not intended to limit the scope of the claims appended hereto. It will be readily apparent to one skilled in the art that other various modifications may be made and equivalents may be substituted for elements in the embodiments chosen for illustration without departing from the spirit and scope of the invention as defined by the claims.

What is claimed is:

1. A method of tuning the size of an nano-active material on a nano-carrier material comprising:
a. providing a starting portion of a carrier material and a starting portion of an active material in a first ratio;
b. adjusting the first ratio, forming a second ratio, thereby tuning the ratio of active material and carrier material;
c. combining the portion of the active material in a vapor phase and the portion of the carrier material in a vapor phase, forming a conglomerate in a vapor phase; and
d. changing the phase of the conglomerate, thereby forming nano-spheres comprising a nano-carrier material decorated with a nano-active material, wherein the size of the nano-active material is dependent upon the second ratio.

2. The method of tuning the size of an nano-active material on a nano-carrier material according to claim 1, wherein the carrier material is selected for its propensity to bond with the active material as the carrier material and the active material phase change from a vapor phase to a solid phase.

3. The method of tuning the size of an nano-active material on a nano-carrier material according to claim 1, wherein the carrier material is selected from among alumina, silica, titania, carbon, and aluminum silicon mixtures.

4. The method of tuning the size of an nano-active material on a nano-carrier material according to claim 1, wherein the active material is selected for its propensity to serve as a reactant.

5. The method of tuning the size of an nano-active material on a nano-carrier material according to claim 1, wherein the active material is selected from among metals, platinum-groove metals, metal compounds and metal oxides.

6. The method of tuning the size of an nano-active material on a nano-carrier material according to claim 1, wherein the size of the nano-active material ranges from 0.1 nanometers to 10 nanometers.

7. The method of tuning the size of an nano-active material on a nano-carrier material according to claim 1, further comprising forming the second ratio based on a known relationship between the ratio of active material to carrier material within the conglomerate and the size of the nano-active material on the nano-spheres.

8. The method of tuning the size of an nano-active material on a nano-carrier material according to claim 7, wherein the known relationship between the ratio of active material to carrier material is determined with a step of calibration prior to providing a starting portion of a carrier material and a starting portion of an active material.

9. A method of calibrating the size of nano-active material in a process of manufacturing nano-active material on a nano-carrier material comprising:
a. performing a first nano-sphere manufacture iteration comprising:
i. providing a portion of a carrier material in a vapor phase and a portion of an active material in a vapor phase in a first ratio;
ii. combining the active material and the carrier material in the first ratio, forming a first conglomerate in a vapor phase;
iii. changing the phase of the conglomerate, thereby forming a first batch of nano-spheres comprising a nano-carrier material decorated with a nano-active material; and
iv. examining the first batch of nano-spheres to determine the size of the nano-active material found on the nano-carrier material;
b. performing a series of n nano-sphere manufacture iterations comprising:
i. adjusting the first ratio, forming a portion of a carrier material in a vapor phase and a portion of an active material in a vapor phase in an e ratio;
ii. combining the active material and the carrier material in the e ratio, forming a n^{th} conglomerate in a vapor phase; and
iii. changing the phase of the conglomerate, thereby forming a n^{th} batch of nano-spheres comprising a nano-carrier material decorated with a nano-active material;
iv. examining the n^{th} batch of nano-spheres to determine the size of the nano-active material found on the nano-carrier material; and
c. recording the relationship between the ratio of a portion of a carrier material in a vapor phase and a portion of an active material in a vapor phase and the size of a resulting nano-active material on a nano-sphere, such that a user is able to manufacture subsequent batches of nano-spheres with appropriately sized nano-active material without performing multiple manufacturing iterations.

10. The method of calibrating the size of nano-active material in a process of manufacturing nano-active material on a nano-carrier material according to claim 9, wherein the carrier material is selected for its propensity to bond with the active material as the carrier material and the active material phase change from a vapor phase to a solid phase.

11. The method of calibrating the size of nano-active material in a process of manufacturing nano-active material on a nano-carrier material according to claim 9, wherein the active material is selected for its propensity to serve as a reactant.

12. A method of tuning a nano-support comprising:
a. providing a nano-support, wherein the nano-support comprises a porous support surface;
b. manufacturing a portion of tuned nano-spheres comprising:
i. providing a starting portion of a carrier material in a vapor phase and a starting portion of an active material in a vapor phase in a first ratio;
ii. combining the portion of the active material and the portion of the carrier material, forming a conglomerate in a vapor phase;
iii. adjusting the first ratio, forming a second ratio, thereby tuning the ratio of active material to carrier material within the conglomerate; and
iv. changing the phase of the conglomerate, thereby forming tuned nano-spheres comprising a nano-carrier material decorated with a nano-active material, wherein a size of the nano-active material is dependent upon the second ratio;
c. impregnating the tuned nano-spheres into the nano-support wherein a retained portion of the tuned nano-spheres are retained on the porous support surface and wherein a run-off portion of the tuned nano-spheres pass through the nano-support; and
d. drying the nano-support, thus bonding and calcining the retained portion of nano-spheres to the porous support surface of the nano-support, forming an at least partially load nano-support.

13. The method of tuning a nano-support according to claim 12 wherein impregnating the tuned nano-spheres with the nano-support comprises:
a. suspending the tuned nano-spheres in a solution, thereby forming a suspension; and
b. mixing the suspension with a quantity of the supports.

14. The method of tuning a nano-support according to claim 12, wherein the suspension further comprises any among a dispersant and surfactant.

15. The method of tuning a nano-support according to claim 12, wherein impregnating the tuned nano-spheres with the nano-support comprises:
a. suspending the tuned nano-spheres in a solution, thereby forming a suspension; and
b. mixing the suspension with a slurry having nano-supports suspended therein.

16. The method of tuning a nano-support according to claim 15 wherein the suspension further comprises any among a dispersant and a surfactant.

17. The method of tuning a nano-support according to claim 15 wherein the slurry comprises any one of organic solvent, aqueous solvent, and a combination thereof.

18. The method of tuning a nano-support according to claim 12, wherein impregnating the tuned nano-spheres with the nano-support comprises:
a. suspending the tuned nano-spheres in a solution, thereby forming a suspension; and
b. injecting the suspension directly into a nano-support.

19. The method of tuning a nano-support according to claim 12, further comprising:
a. performing at least one additional iteration of impregnating a portion of the tuned nano-spheres with the at least partially loaded nano-support such that the at least one additional portion of nano-spheres is bonded to the porous support surface; and
b. performing at least one additional iteration of drying the nano-support, thus bonding and calcining the at least one additional portion of nano-spheres to the at least partially loaded nano-support, forming an at least twice loaded nano-support.

20. The method of tuning a nano-support according to claim 12, wherein the step of manufacturing a portion of tuned nano-spheres further comprises:
a. adjusting the second ratio a n^{th} additional time, forming a n^{th} ratio, thereby tuning the ratio of active material to carrier material within the conglomerate.

21. The method of tuning a nano-support according to claim 12, wherein the step of manufacturing a portion of tuned nano-spheres further comprises:
a. optimizing the ratio of active material to carrier material such that the resulting size of the tuned nano-spheres is minimized.

22. The method of tuning a nano-support according to claim 21, further comprising:
a. determining an optimal amount of nano-active material to be loaded into a nano-support based on a given application; and
b. performing n iterations of impregnating a portion of the tuned nano-spheres with the at least partially loaded nano-support and n iterations of drying the nano-support, such that n additional portions of nano-spheres are bonded to the porous support surface, wherein n is equal to a integer which results in the amount of nano-active material to be loaded into a nano-support most closely matching the optimal amount.

23. A method of manufacturing a tunable-sized nano-active material on a nano-carrier material comprising:
a. providing a carrier material and an active material;
b. mixing a portion of the active material in a vapor phase and a portion of the carrier material in a vapor phase, forming a conglomerate in a vapor phase, wherein the portion of the active material in the vapor phase and the portion of the carrier material in the vapor phase are mixed in a given ratio;
c. adjusting the ratio of the portion of the active material in the vapor phase and the portion of the carrier material in the vapor phase;
d. changing the phase of the conglomerate, thereby forming nano-spheres comprising nano-carrier material decorated with nano-active material, wherein the ratio of the portion of the active material in the vapor phase and the portion of the carrier material in the vapor phase dictates the size of the nano-active material found on the nano-carrier material

24. The method of manufacturing a tunable-sized nano-active material on a nano-carrier material according to claim 23, wherein the carrier material is selected for its propensity to bond with the active material while the carrier material is in a vapor phase and while the active material is in a vapor phase without forming a composite material;

25. An apparatus for tuning the size of an nano-active material on a nano-carrier material comprising:
a. a means for providing a carrier material in a vapor phase;
b. a means for providing an active material in a vapor phase;
c. a means for combining the carrier material in a vapor phase and the active material in a vapor phase, forming a conglomerate in a vapor phase;
d. a means for tuning the ratio of carrier material to active material in the conglomerate;
e. a means for changing the phase of the conglomerate, thereby forming nano-spheres comprising a nano-carrier material decorated with a nano-active material.
